(19) United States
(12) Patent Application Publication
(10) Pub. No.: US 2026/0011610 A1
(43) Pub. Date: Jan. 8, 2026

(54) SEMICONDUCTOR STRUCTURE AND FORMATION METHOD THEREOF

(71) Applicant: Winbond Electronics Corp., Taichung CIty (TW)

(72) Inventor: Hung-Chin LIN, Tainan City (TW)

(21) Appl. No.: 19/050,323

(22) Filed: Feb. 11, 2025

(30) Foreign Application Priority Data
Jul. 4, 2024 (TW) 113125117

(51) Int. Cl. H01L 21/66; H10B 12/00

(52) U.S. Cl. CPC H01L 22/32; H10B 12/053; H10B 12/34; H10B 12/482

(57) ABSTRACT

A semiconductor structure and a formation method thereof are provided. The semiconductor structure includes a substrate, a word line, a bit line conductive layer, a detection element, and an opening. The substrate includes a plurality of active regions and an isolation region surrounding the plurality of active regions. The word line is disposed in the substrate and is disposed in the plurality of active regions. The bit line conductive layer is disposed on the word line. The detection element is disposed in the isolation region. The opening penetrates through the bit line conductive layer and exposes the word line and the plurality of active regions, wherein the opening is in contact with the detection element.

### CROSS REFERENCE TO RELATED APPLICATIONS

This application claims priority of Taiwan Patent Application No. 113125117, filed on Jul. 4, 2024, the entirety of which is incorporated by reference herein.

### TECHNICAL FIELD

The present disclosure relates to a semiconductor structure and a formation method thereof, and, in particular, it relates to a semiconductor structure including an opening, and a formation method thereof.

### BACKGROUND

As semiconductor devices shrink, memory devices with buried word lines have been developed to increase integration and improve performance. However, this continuous reduction in size causes defects such as seams to form in components, which adversely affects the performance of semiconductor devices. In addition, the reliability of the semiconductor device is reduced because it is difficult to detect defects in the components.

### SUMMARY

In some embodiments, a semiconductor structure is provided. The semiconductor structure includes a substrate, a word line, a bit line conductive layer, a detection element, and an opening. The substrate includes a plurality of active regions and an isolation region surrounding the plurality of active regions. The word line is disposed in the substrate and is disposed in the plurality of active regions. The bit line conductive layer is disposed on the word line. The detection element is disposed in the isolation region. The opening penetrates through the bit line conductive layer and exposes the word line and the plurality of active regions, wherein the opening is in contact with the detection element.

In some embodiments, a method of forming a semiconductor structure is provided. The formation method includes providing a substrate. An isolation region including a detection element is formed in the substrate, wherein the isolation region defines a plurality of active regions. A word line is formed in the substrate and is formed in the plurality of active regions. A bit line conductive layer is formed on the word line. An opening is formed in the bit line conductive layer, such that the opening penetrates the bit line conductive layer and exposes the word line and the plurality of active regions, so that the opening is in contact with the detection element.

### BRIEF DESCRIPTION OF THE DRAWINGS

FIGS. 1A, 2A, 3A, 4A, 5A, 6A, 7A, 8A, and 9A show schematic circuit layout views of a semiconductor structure according to some embodiments of the present disclosure, respectively.

FIGS. 1B, 1C, 2B, 2C, 3B, 3C, 4B, 4C, 5B, 6B, 7B, 8B, and 9B show schematic cross-sectional views of a semiconductor structure according to some embodiments of the present disclosure, respectively.

### DETAILED DESCRIPTION

In the present disclosure, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For convenience of description, hereinafter, the X-axis direction is the first direction D1 (length direction), the Y-axis direction is the second direction D2 (width direction), and the Z-axis direction is the third direction D3 (thickness/height/depth direction). In some embodiments, the schematic circuit layout views described herein are schematic top view observing the XY plane, and the schematic cross-sectional views described herein are schematic cross-sectional views taken along a line segment on the XY plane.

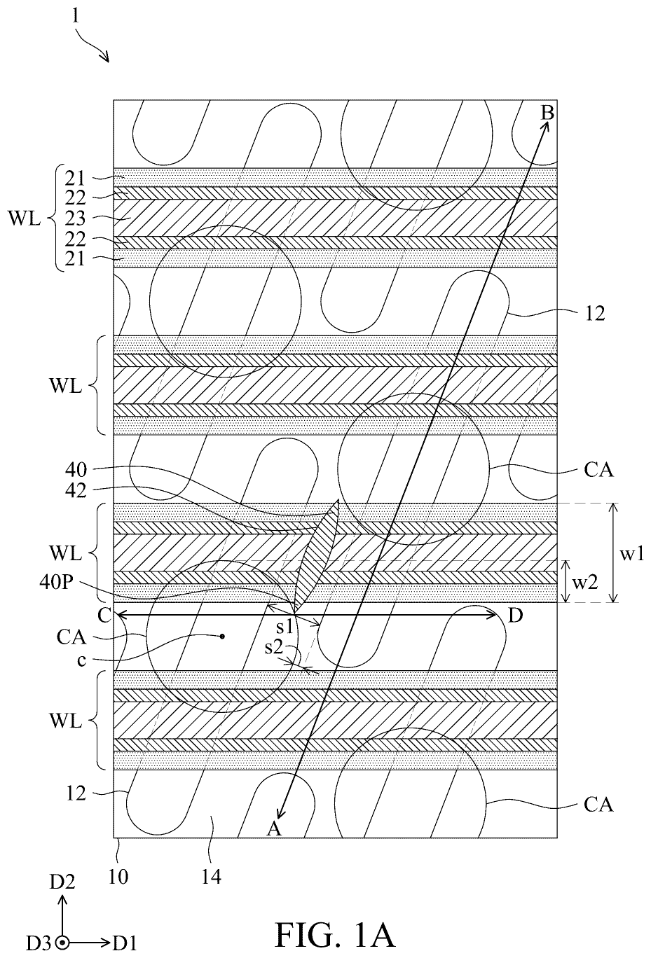

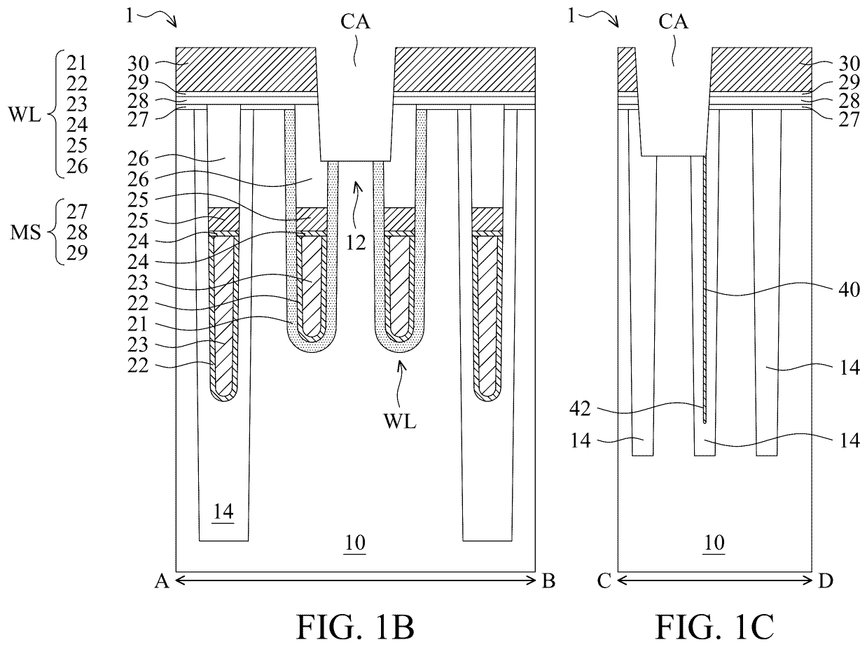

FIG. 1A shows a schematic circuit layout view of the semiconductor structure 1. The first direction D1 and the second direction D2 are perpendicular to each other. First, a substrate 10 is provided. The substrate 10 may be, for example, a silicon wafer, a semiconductor-on-insulator substrate, or a bulk semiconductor substrate.

The substrate 10 may include a plurality of active regions 12 and an isolation region 14 surrounding the active regions 12. The active regions 12 may be arranged in an array in the substrate 10. In some embodiment, one active region 12 extends along a direction that is angled with the first direction D1 and is parallel to another active region 12. The isolation region 14 may include an oxide, for example, silicon oxide, and may be a shallow trench isolation structure. The isolation region 14 may be formed in the substrate 10 by performing such as etching and deposition processes, so that the isolation region 14 may define the plurality of active regions 12. Thus, two adjacent active regions 12 are separated from each other.

The semiconductor structure 1 may include a plurality of word lines WL disposed in the plurality of active regions 12 in the substrate 10 as buried word lines. The top surface of the word line WL may be lower than the top surface of the substrate 10. The word lines WL may extend along the first direction D1 and may be spaced apart in the second direction D2. In some embodiment, after further processes are performed, the word line WL may be used as a word line or a portion of a word line in a DRAM.

FIG. 1B and FIG. 1C show schematic cross-sectional views of the semiconductor structure 1 taken along the line segment A-B and the line segment C-D shown in FIG. 1A, respectively. The line segment A-B is parallel to the extending direction of the active region 12, and the line segment C-D is parallel to the extending direction of the word line WL. As shown in FIGS. 1A to 1C, the word line WL may include a first dielectric layer 21, a first liner 22, a first conductive layer 23, a second liner 24, a second conductive layer 25, and a second dielectric layer 26. The first dielectric layer 21 may be disposed on the substrate 10. The first conductive layer 23 may be disposed on the first dielectric layer 21. The second conductive layer 25 may be disposed on the first conductive layer 23. The second dielectric layer 26 may be disposed on the second conductive layer 25. The first liner 22 may be disposed between the first dielectric layer 21 and the first conductive layer 23. The second liner 24 may be disposed between the first conductive layer 23 and the second conductive layer 25. The first liner 22 and the second liner 24 may together surround the first conductive layer 23 such that the first conductive layer 23 is separated from the second conductive layer 25 and prevent (material) compositions in the first conductive layer 23 from diffusing into other components. In other embodiments, the first liner 22 and/or the second liner 24 may be omitted.

As shown in FIGS. 1A and 1B, trenches (not shown) may be formed in the active region 12 and the isolation region 14 of the substrate 10 by an etching process. Then, the first dielectric layer 21 may be conformally formed in the trenches by a deposition process. The first dielectric layer 21 may serve as a gate dielectric layer for word lines in the memory device. The first dielectric layer 21 may include an oxide such as silicon oxide, a nitride such as silicon nitride, an oxynitride such as silicon oxynitride, the like, or a combination thereof. Then, the first liner 22 may be conformally formed on the first dielectric layer 21 by a deposition process. The first liner 22 may include a conductive material, for example, polycrystalline silicon, amorphous silicon, metals such as tungsten, gold, silver, copper, cobalt, or the like, metal nitrides such as titanium nitride, conductive metal oxides, other suitable materials, or a combination thereof. The first liner 22 may include titanium nitride. Then, the first conductive layer 23 may be blanketly formed on the first liner 22 by a deposition process. In some embodiments, the first conductive layer 23 may include tungsten. In some embodiments, the top surface of the first conductive layer 23 is aligned with the top surface of the first liner 22. Then, the second liner 24 may be conformally formed on the first liner 22 and the first conductive layer 23 by a deposition process. The material and formation method of the second liner 24 may be the same as or different from that of the first liner 22. The second liner 24 may include titanium nitride. The second conductive layer 25 may be blanketly formed on the second liner 24 by a deposition process. The material and formation method of the second conductive layer 25 may be the same as or different from that of the first conductive layer 23. The second conductive layer 25 may include polycrystalline silicon. The second dielectric layer 26 may be blanketly formed on the second conductive layer 25 by a deposition process. The material and formation method of the second dielectric layer 26 may be the same as or different from that of the first dielectric layer 21. In some embodiments, the second dielectric layer 26 may include silicon nitride.

As shown in FIGS. 1B and 1C, the semiconductor structure 1 may further include a mask structure MS disposed on the word line WL. The mask structure MS may be disposed between the word line WL and the subsequently formed bit line conductive layer 30. The mask structure MS may include a first mask 27, a second mask 28, and a third mask 29 sequentially disposed on the second dielectric layer 26. The mask structure MS may include oxide, nitride, oxynitride, carbide, or a combination thereof. In some embodiments, the first mask 27 may be an oxide formed from tetraethoxysilane (TEOS) as a precursor, the second mask 28 may be a nitride, and the third mask 29 may be an oxide.

As shown in FIG. 1B and FIG. 1C, the bit line conductive layer 30 may be formed on the word line WL. The material and formation method of the bit line conductive layer 30 may be the same as or different from that of the first conductive layer 23 and/or the second conductive layer 25. The bit line conductive layer 30 may include polycrystalline silicon. In some embodiments, after further processes are performed, the bit line conductive layer 30 may be used as a bit line or a portion of a bit line in the DRAM.

As shown in FIGS. 1A to 1C, the isolation region 14 in the semiconductor structure 1 may include a detection element 40. In some embodiments, during the formation of the isolation region 14, seams, air gaps, defects, or the like may be formed in the isolation region 14 due to the influence of the aspect ratio of the trench used to form the isolation region, parameters of the deposition process, or other parameters. Then, during subsequent processes, materials used to form other components may fill in the seams, the air gaps, the defects, or the like in the isolation region 14, causing short circuits between components of the semiconductor structure 1. In the present disclosure, the filler filled in the seams, the air gaps, the defects, or the like may be used as the detection element 40, and whether the seams, the air gaps, the defects, or the like exist in the isolation region 14 may be determined by determining the material composition of the detection element 40. Then, the semiconductor structure 1 may be detected, thereby improving the reliability of the semiconductor structure 1. For example, once the material of the detection element 40 is different from the material of the isolation region 14, it means that the seams, the air gaps, the defects, or the like are present in the isolation region 14.

In some embodiments, the drawings of the present disclosure take the detection element 40 as a filler filled in the seam 42 as an example, but the present disclosure is not limited thereto. In some embodiments, after the first liner 22 is formed or after the first conductive layer 23 is formed, optionally, the material of the first liner 22, or the materials of the first liner 22 and the first conductive layer 23 may be fill seams 42 in the isolation region 14. Therefore, the detection element 40 may include the material of the first liner 22, and the detection element 40 may further include the material of the first conductive layer 23. In detail, the material of the first liner 22 may have completely filled the seam 42 in the isolation region 14, or the material of the first liner 22 and the material of the first conductive layer 23 may have jointly filled the seam 42 in the isolation region 14. Then, the material of the first liner 22 and the material of the first conductive layer 23 are jointly filled in the seam 42 in the isolation region 14 as an example for description. Furthermore, the detection element 40 may be physically connected to the first liner 22 and/or the first conductive layer 23 in the word line WL. In some embodiments, the detection element 40 may be disposed between two adjacent active regions 12. In detail, as shown in FIG. 1A, since the aspect ratio between two adjacent active regions 12 may be greater, the detection element 40 tends to appear between two adjacent active regions 12. For example, since there is a narrow spacing between two parallel active regions AA (for example, the first distance s1 described below), the detection element 40 tends to appear between two adjacent active regions 12.

As shown in FIGS. 1A to 1C, the opening CA may be formed in the bit line conductive layer 30 by an etching process. During the formation of the opening CA, a portion of the bit line conductive layer 30, a portion of the mask structure MS, a portion of the word line WL, and a portion of the substrate 10 may be removed, so that the opening CA penetrates the bit line conductive layer 30 and the mask structure MS. The opening CA exposes an upper portion of the word line WL and the plurality of active regions 12, so that the opening CA may be in contact with the detection element 40. In some embodiments, the opening CA exposes the second dielectric layer 26 and the first dielectric layer 21 of the word line WL. Further processes may be performed to form a bit line contact in the opening CA. In some embodiments, the opening CA may have a center c, and the center c may be located on the active region 12 or on the isolation region 14. As shown in FIG. 1A, the center c of the opening CA may be located on the isolation region 14 so that the opening CA may be in contact with the detection element 40. In some embodiments, the center c may be the geometric center of the opening CA, the intersection of the diagonals of the opening CA, or the center c defined in other suitable ways. In some embodiments, when viewed from a top view, the opening CA may have a circular, oval, rectangular, polygonal, bone-shaped, dumbbell-shaped, V-shaped, or other similar shape, but the present disclosure is not limited thereto.

As shown in FIG. 1A, in a top view, two adjacent active regions 12 may be separated by a first distance s1. Wherein the first distance s1 may be the shortest distance between two adjacent active regions 12. The opening CA disposed on one active region 12 of the two adjacent active regions 12 is separated from the other active region 12 of the two active regions 12 by a second distance s2. The second distance s2 may be the shortest distance between the opening CA and the other active region 12. The second distance s2 may be less than or equal to half of the first distance s1. For example, the ratio of the second distance s2 to the first distance s1 (the second distance s2/the first distance s1) may be 0.5, 0.45, 0.4, 0.35, 0.33, 0.3, 0.2, 0.1, or any value or any range of values between the aforementioned values, but the present disclosure is not limited thereto. Therefore, in the case where the second distance s2 is less than or equal to half of the first distance s1, the opening CA may be in contact with the detection element 40. In some embodiments, the second distance s2 may be greater than 0. Therefore, when the second distance s2 is greater than 0, the opening CA may be prevented from contacting two adjacent active regions 12 at the same time, thereby avoiding causing a short circuit between the two adjacent active regions 12.

As shown in FIG. 1A, in a top view, the detection element 40 may have a protruding portion 40P protruding from the word line WL, and the opening CA may overlap with the protruding portion 40P of the detection element 40 to effectively determine whether the detection element 40 exists in the isolation region 14. As shown in FIG. 1A, in a top view, the word line WL may have a first width w1, and the exposed portion of the word line WL exposed by the opening CA may have a second width w2. In some embodiments, the second width w2 may be greater than or equal to one-third of the first width w1. In some embodiments, the second width w2 may be less than or equal to one-half of the first width w1. For example, the ratio of the second width w2 to the first width w1 (the second width w2/the first width w1) may be 0.33, 0.34, 0.4, 0.43, 0.45, 0.47, 0.5, or any value or any range of values between the aforementioned values, but the present disclosure is not limited thereto. Therefore, the opening CA may be in contact with the detection element 40.

In the following, the same or similar reference numerals will not be described repeatedly.

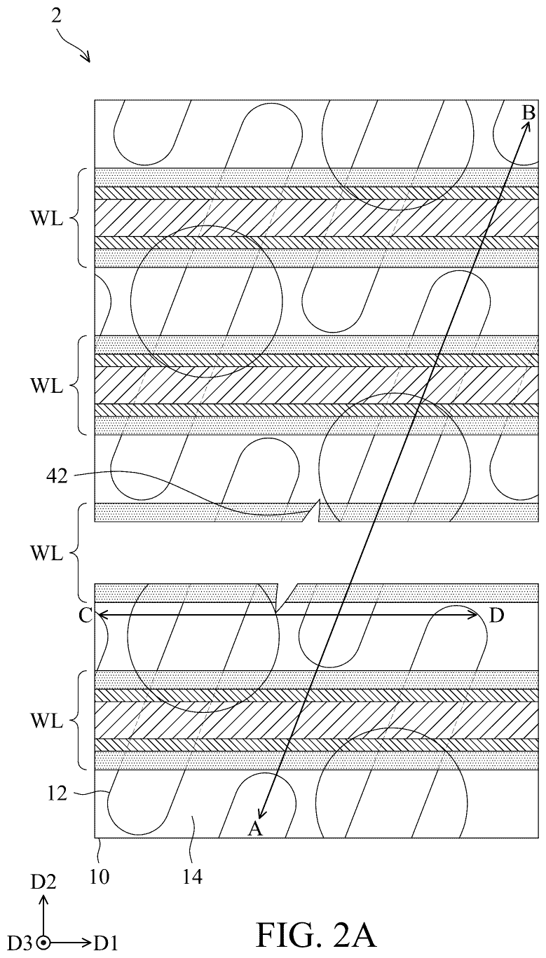

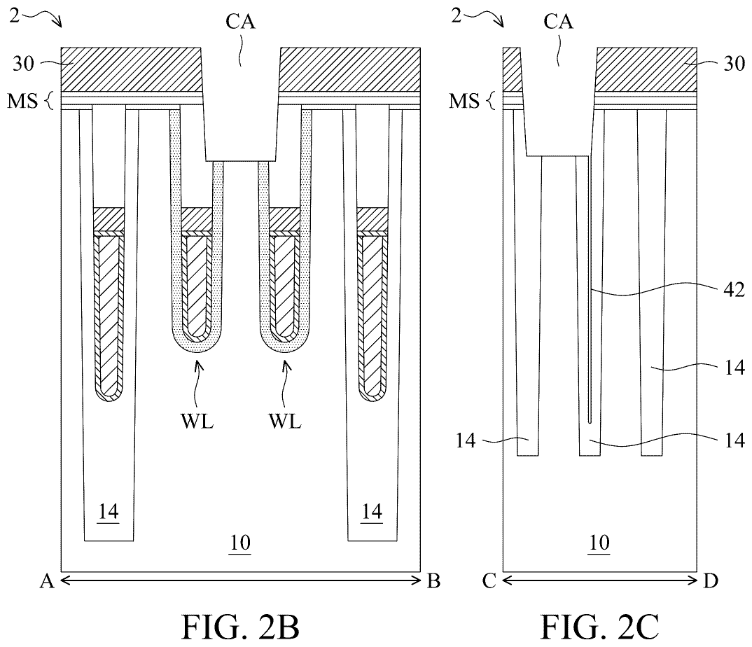

FIG. 2B and FIG. 2C show schematic cross-sectional views of the semiconductor structure 2 taken along the line segment A-B and the line segment C-D shown in FIG. 2A, respectively. Referring to FIGS. 2A to 2C, a cleaning process is performed to remove the detection element through the opening CA. The cleaning process may include a wet cleaning process. For example, a wet cleaning process may have high selectivity for conductive materials and have low selectivity for dielectric materials. As shown in FIGS. 2A to 2C, the cleaning process is performed to remove the detection element 40 and expose the seam 42 located in the isolation region 14. In other words, the cleaning process may remove the materials of the first liner 22 and the first conductive layer 23 located in the seam 42. On the other hand, as shown in FIGS. 1A and 2A, since the detection element 40 is connected to the first liner 22 and the first conductive layer 23 of the word line WL, when the cleaning process is performed, the first liner 22 and the first conductive layer 23 in the word line WL are also removed through the opening CA, and the first dielectric layer 21 in the word line WL is remained. Since it can be clearly identified in the top view whether the seam 42 and the first liner 22 and the first conductive layer 23 in the word line WL are removed, it is helpful to detect whether the detection element 40 exists in the isolation region 14 during subsequent optical inspection. In detail, due to the small size of the detection element 40, it is generally difficult to detect whether the detection element 40 exists by the optical instruments. According to some embodiments of the present disclosure, the first liner 22 and the first conductive layer 23 of the detection element 40 may be removed by the cleaning process, and the first liner 22 and the first conductive layer 23 of the word line WL connected to the detection element 40 may also be removed. In this way, during the optical inspection, it can be easily detected whether the detection element 40 exists in the isolation region 14 by detecting the defect that the word line WL is partially hollowed out. Thereby, whether the seams, the air gaps, the defects, or the like are present in the isolation region 14 may be detected.

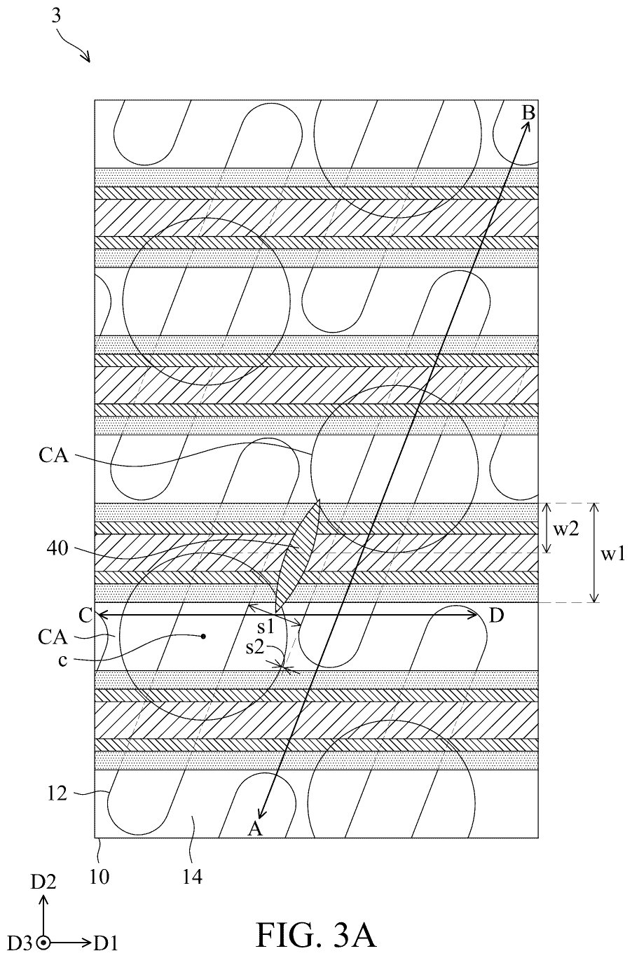

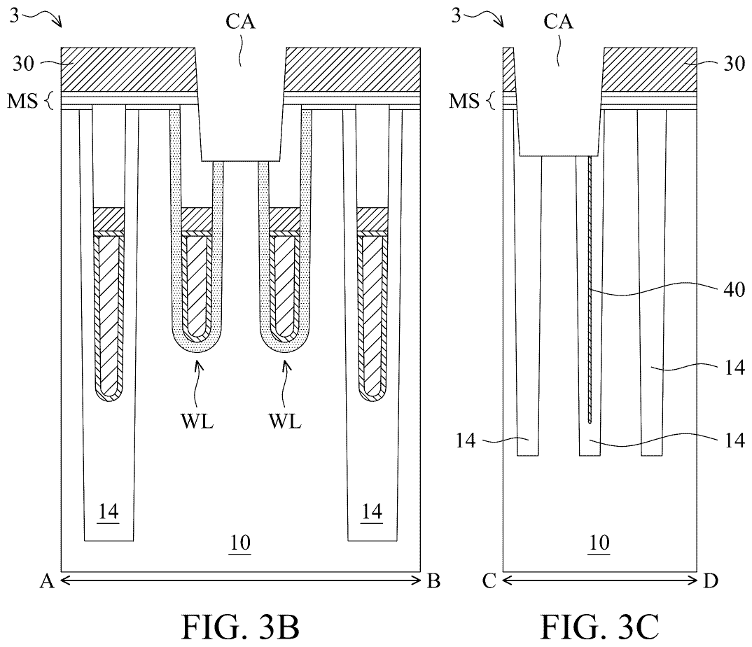

Referring to FIG. 3A, which shows a schematic circuit layout view of a semiconductor structure 3 according to some embodiments. Referring to FIG. 3B and FIG. 3C, which show schematic cross-sectional views of the semiconductor structure 3 taken along the line segment A-B and the line segment C-D shown in FIG. 3A according to some embodiments, respectively. In some embodiments, as shown in FIGS. 3A to 3C, the ratio of the second distance s2 to the first distance s1 may be 0.2, and the ratio of the second width w2 to the first width w1 may be 0.5. In some embodiments, the radius of the opening CA as shown in FIG. 3A may be greater than the radius of the opening CA as shown in FIG. 1A, so that the opening CA may be in contact with the detection element 40.

In the following, parameters such as the location, size, quantity, depth, and shape of the openings may be adjusted so that the openings may be effectively in contact with the detection element 40. In the present disclosure, the aforementioned semiconductor structures 1 to 3 and the later-described semiconductor structures 4 to 9 may be combined arbitrarily.

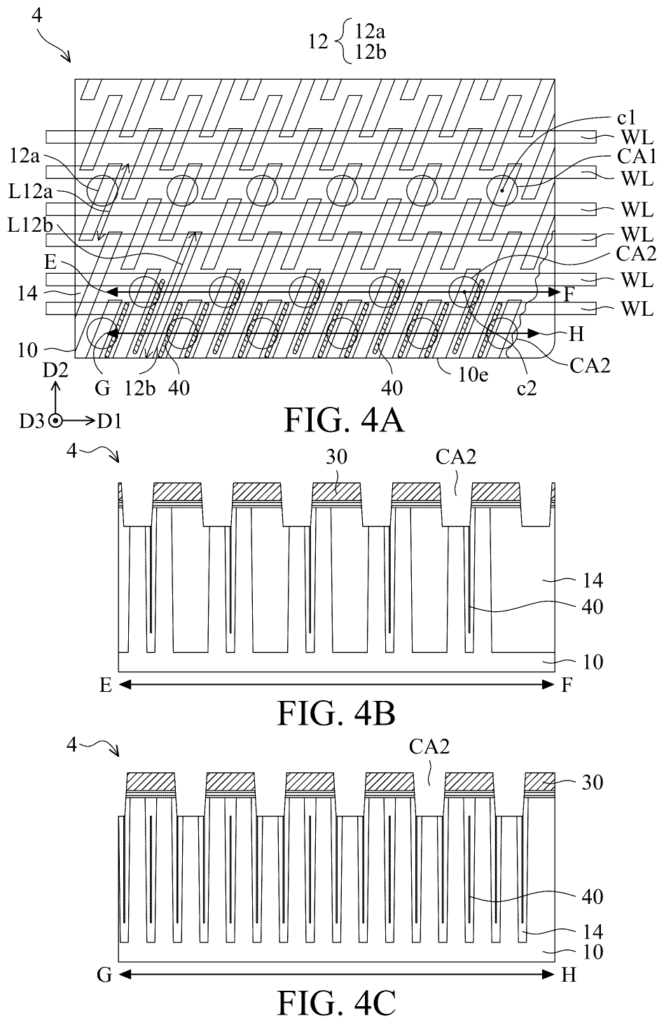

Referring to FIG. 4A, which shows a schematic circuit layout view of a semiconductor structure 4 according to some embodiments. Referring to FIGS. 4B and 4C, which show schematic cross-sectional views of the semiconductor structure 4 taken along the line segment E-F and the line segment G-H shown in FIG. 4A according to some embodiments, respectively. Wherein, the line segment E-F and the line segment G-H are parallel to the extending direction of the word line WL. In some embodiments, as shown in FIG. 4A, the plurality of active regions 12 may include active regions 12 having different lengths. In some embodiments, the plurality of active regions 12 may include a first active region 12a and a second active region 12b. In some embodiments, the first active region 12a may be disposed at a central portion of the substrate 10, and the second active region 12b may be disposed adjacent the edge 10e of the substrate 10. In other words, the second active region 12b may be closer to the edge 10e of the substrate 10 than the first active region 12a. In some embodiments, the second active region 12b may serve as a dummy active region. In some embodiments, the opening CA of the present disclosure may be disposed only in the second active region 12b and does not dispose in the first active region 12a. Therefore, the design of the opening for accommodating bit line contacts in the first active area 12a does not be changed, thereby improving the reliability of the first active area 12a. In other embodiments, the opening CA of the present disclosure may be disposed in both the second active region 12b and the first active region 12a at the same time, thereby comprehensively changing the design of the opening to reduce process complexity.

In some embodiments, the extending length L12b of the second active region 12b may be greater than the extending length L12a of the first active region 12a as a worse condition. Thus, the seams, the air gaps, the defects, or the like are more likely to form in the isolation regions 14 between the second active regions 12b. For example, a plurality of first active regions 12a and a plurality of second active regions 12b may jointly form a memory array (wherein the first active region 12a performs a memory function, and the second active region 12b does not perform a memory function but only is a dummy active region), so that the seams, the air gaps, the defects, or the like are more likely to form on the edge of the memory array.

In some embodiments, as shown in FIGS. 4A and 4B, the opening CA1 may be disposed in the first active region 12a, and the opening CA2 may be disposed in the second active region 12b. The opening CA1 may be between any two adjacent word lines WL except the two word lines WL closest to the edge 10e of the substrate 10, and the opening CA2 may be between the two word lines WL closest to the edge 10e of the substrate 10. As shown in FIGS. 4A and 4C, no opening is provided between the word line WL closest to the edge 10e of the substrate 10 and the edge 10e of the substrate 10. As shown in FIG. 4A, the center c2 of the opening CA2 may be located on the second active region 12b, so that the opening CA2 is in contact with the detection element 40 (as shown in FIG. 4B). It should be noted that, although the subsequent semiconductor structures 5 to 9 do not show openings disposed in the first active region 12a, the openings may be disposed in the first active region 12a by the same or different manner as the openings disposed in the semiconductor structures 1 to 4.

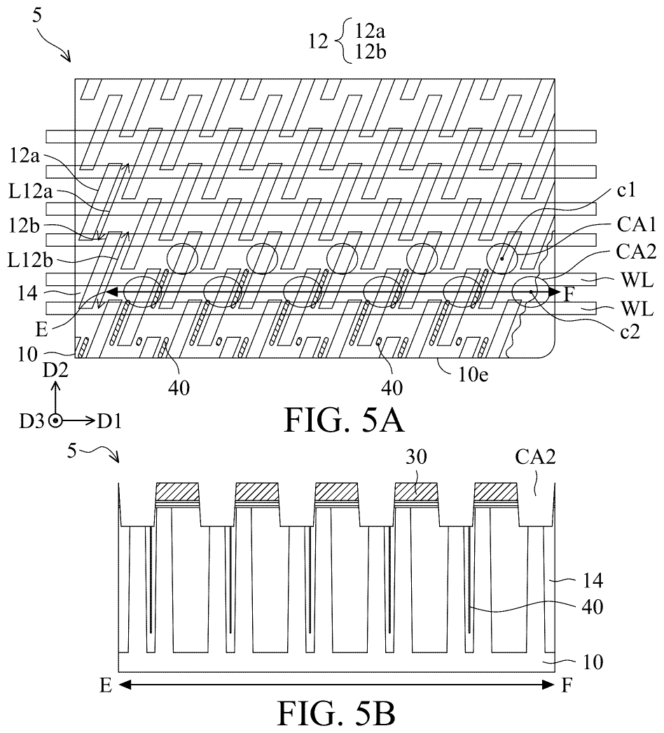

Referring to FIG. 5A, which shows a schematic circuit layout view of a semiconductor structure 5 according to some embodiments. Referring to FIG. 5B together, which shows a schematic cross-sectional view of the semiconductor structure 5 taken along the line segment E-F shown in FIG. 5A according to some embodiments. In some embodiments, the extending length L12b of the second active region 12b may be equal to the extending length L12a of the first active region 12a as a normal condition. Thus, the seams, the air gaps, the defects, or the like may be arbitrarily occurred in the isolation regions 14 between the second active regions 12b and/or in the isolation regions 14 between the first active regions 12a. In the following, it is described that the seams, the air gaps, the defects, or the like are generated in the isolation region 14 between the second active regions 12b. As shown in FIG. 5A, the opening CA2 may be closer to the edge 10e of the substrate 10 than the opening CA1, and the area of the opening CA2 may be greater than the area of the opening CA1, so that the opening CA2 may be in contact with the detection element 40 (as shown in FIG. 5B). In other words, the area of the opening CA2 which is closer to the edge 10e of the substrate 10 may be greater than the area of the opening CA1 which is away from the edge 10e of the substrate 10. For example, the ratio of the areas of opening CA2 and opening CA1 (the area of the opening CA2/the area of the opening CA1) may be 1.1, 1.2, 1.3, 1.4, 1.5, 1.75, 2, or any value or any range of values between the aforementioned values, but the present disclosure is not limited thereto. In some embodiments, as shown in FIG. 5A, no opening is provided between the word line WL closest to the edge 10e of the substrate 10 and the edge 10e of the substrate 10.

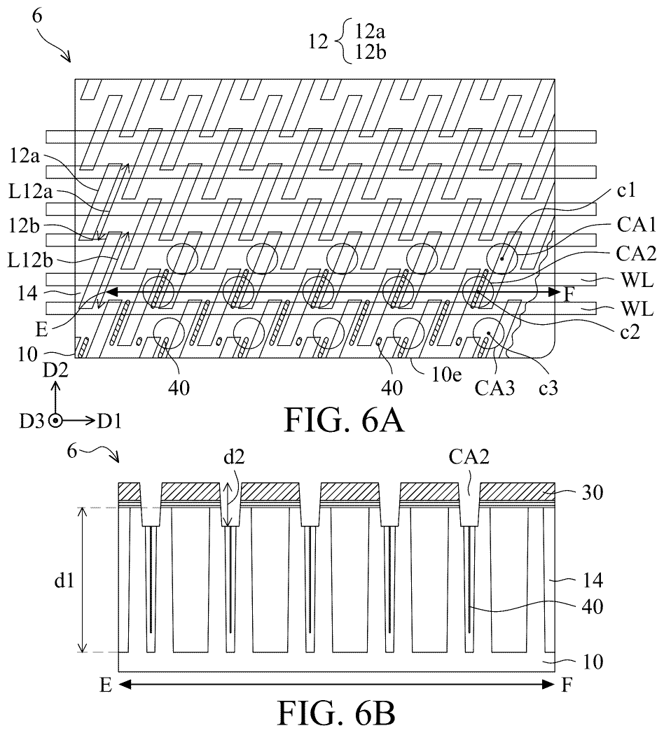

Referring to FIG. 6A, which shows a schematic circuit layout view of a semiconductor structure 6 according to some embodiments. Referring to FIG. 6B, which shows a schematic cross-sectional view of the semiconductor structure 6 taken along the line segment E-F shown in FIG. 6A according to some embodiments. As shown in FIG. 6A, the center c1 of the opening CA1 may be located on the second active region 12b, and the center c2 of the opening CA2 may be located on the isolation region 14, so that the opening CA2 may be in contact with the detection element 40 (as shown in FIG. 6B). In some embodiments, as shown in FIG. 6A, an opening CA3 may be further provided. The opening CA3 may be disposed between the word line WL closest to the edge 10e of the substrate 10 and the edge 10e of the substrate 10. As shown in FIGS. 6A and 6B, both openings CA2 and CA3 may be in contact with the detection element 40. In some embodiments, in the normal direction of the substrate 10, the isolation region 14 has a first depth d1, and the openings CA1 to CA3 may have a second depth d2. In some embodiments, the ratio of the second depth d2 to the first depth d1 (the second depth d2/the first depth d1) may be 0.1, 0.15, 0.2, 0.25, 0.3, or any value or any range of values between the aforementioned value, but the present disclosure is not limited thereto.

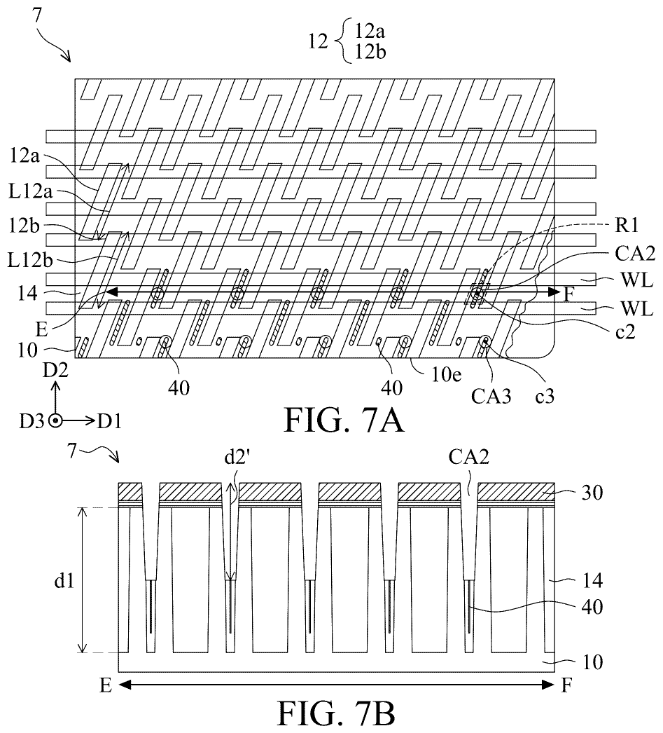

Referring to FIG. 7A, which shows a schematic circuit layout view of a semiconductor structure 7 according to some embodiments. Referring to FIG. 7B together, which shows a schematic cross-sectional view of the semiconductor structure 7 taken along the line segment E-F shown in FIG. 7A according to some embodiments. In some embodiments, the areas (or widths) of the openings CA2 and CA3 as shown in FIGS. 7A and 7B are smaller than that of the openings CA2 and CA3 as shown in FIGS. 6A and 6B. The second depth d2′ of the openings CA2 and CA3 as shown in FIGS. 7A and 7B may be greater than the second depth d2 of the openings CA2 and CA3 as shown in FIGS. 6A and 6B. The opening CA2 shown in FIG. 7A is located in a region formed by two adjacent second active regions 12b and two adjacent word lines WL, for example, in a region R1 with a parallelogram shape. The opening CA2 is disposed between two adjacent word lines WL and does not contact the word lines WL. The opening CA2 is only disposed in the isolation region 14 and does not dispose in the word line WL.

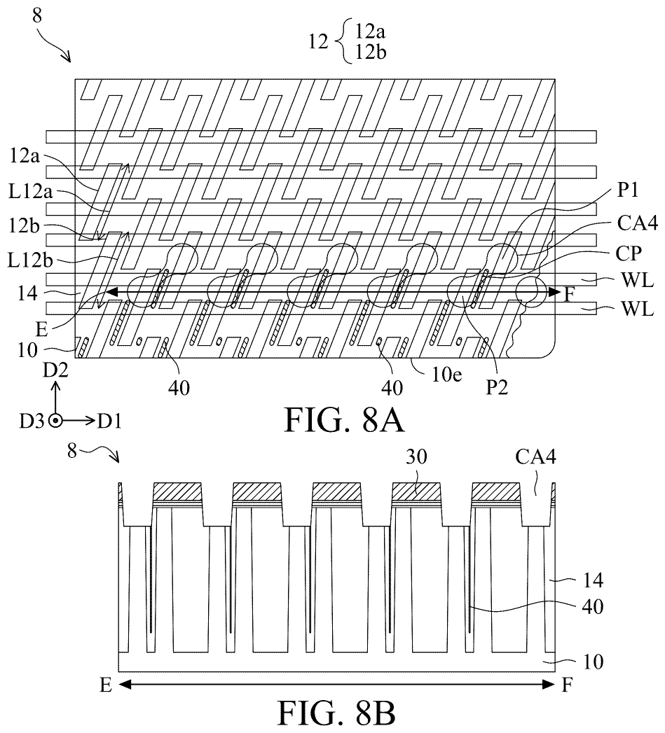

Referring to FIG. 8A, which shows a schematic circuit layout view of a semiconductor structure 8 according to some embodiments. Referring to FIG. 8B together, which shows a schematic cross-sectional view of the semiconductor structure 8 taken along the line segment E-F shown in FIG. 8A according to some embodiments. In some embodiments, the opening CA4 may extend across at least two active regions 12 of the plurality of active regions 12. For example, the opening CA4 may extend across two, three, four, or another suitable number of active regions 12 of the plurality of active regions 12. In some embodiments, the opening CA4 may include a first portion P1, a second portion P2, and a connection portion CP. In some embodiments, the first portion P1 may be disposed on one active region 12 of the plurality of active regions 12, the second portion P2 may be disposed on another active region 12 of the plurality of active regions 12, and the connection portion CP may connect the first portion P1 and the second portion P2. In some embodiments, the connection portion CP may be disposed on the isolation region 14 so that the opening CA4 may be in contact with the detection element 40.

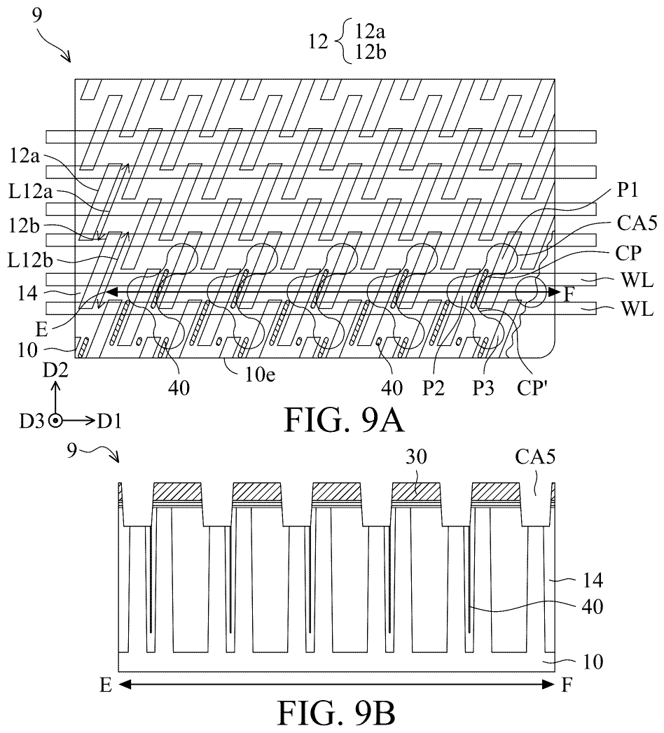

Referring to FIG. 9A, which shows a schematic circuit layout view of a semiconductor structure 9 according to some embodiments. Referring to FIG. 9B together, which shows a schematic cross-sectional view of the semiconductor structure 9 taken along the line segment E-F shown in FIG. 9A according to some embodiments. In some embodiments, the opening CA4 may extend across at least two active regions 12 of the plurality of active regions 12. For example, the opening CA4 may extend across two, three, four, or another suitable number of the active regions 12 of the plurality of active regions 12. In some embodiments, the opening CA5 may include a first portion P1, a second portion P2, a third portion P3, and connection portions CP and CP′. In some embodiments, the first portion P1 may be disposed on one active region 12 of the plurality of active regions 12, the second portion P2 may be disposed on another active region 12 of the plurality of active regions 12, and the third portion P3 may be disposed on another active region 12 of the plurality of active regions 12. The connection portion CP may connect the first portion P1 and the second portion P2, and the connection portion CP′ may connect the second portion P2 and the third portion P3. In some embodiments, the connection portions CP and CP′ may be disposed on the isolation region 14, so that the opening CA5 may be in contact with the detection element 40.

In summary, the semiconductor structure of the present disclosure includes an opening in contact with a detection element, so as to detect the reliability of the semiconductor structure by the opening and the detection element. Furthermore, the semiconductor structure and the formation method thereof of the present disclosure may further improve the resolution of the optical instrument when detecting the reliability of the semiconductor structure with optical instruments.

The foregoing outlines features of several embodiments of the present disclosure, so that a person of ordinary skill in the art may better understand the aspects of the present disclosure. A person of ordinary skill in the art should appreciate that the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate comprising a plurality of active regions and an isolation region surrounding the plurality of active regions;
a word line disposed in the substrate and disposed in the plurality of active regions;
a bit line conductive layer disposed on the word line;
a detection element disposed in the isolation region; and
an opening penetrating through the bit line conductive layer and exposing the word line and the plurality of active regions, wherein the opening is in contact with the detection element.

2. The semiconductor structure as claimed in claim 1, wherein in a top view, two adjacent active regions in the plurality of active regions are separated by a first distance, the opening disposed on one active region of the two adjacent active regions is separated from the other active region of the two adjacent active regions by a second distance, and the second distance is less than or equal to half of the first distance.

3. The semiconductor structure as claimed in claim 1, wherein in a top view, the word line has a first width, and an exposed portion of the word line has a second width, and the second width is greater than or equal to one-third of the first width.

4. The semiconductor structure as claimed in claim 1, wherein the plurality of active regions comprises a first active region and a second active region, the second active region is closer to an edge of the substrate than the first active region, and an extending length of the second active region is greater than an extending length of the first active region.

5. The semiconductor structure as claimed in claim 1, wherein the plurality of active regions comprises a first active region and a second active region, the second active region is closer to an edge of the substrate than the first active region, and an area of the opening close to the edge of the substrate is greater than an area of the opening away from the edge of the substrate.

6. The semiconductor structure as claimed in claim 1, wherein the opening has a center and the center is located on the isolation region.

7. The semiconductor structure as claimed in claim 1, wherein the opening extends across at least two active regions of the plurality of active regions.

8. The semiconductor structure as claimed in claim 7, wherein the opening comprises:
a first portion disposed on one active region of the plurality of active regions; and
a second portion disposed on another active region of the plurality of active regions.

9. The semiconductor structure as claimed in claim 8, wherein the opening further comprises:
a connection portion connecting the first portion and the second portion.

10. The semiconductor structure as claimed in claim 9, wherein the connection portion is disposed on the isolation region.

11. The semiconductor structure as claimed in claim 7, wherein the opening extends across at least three active regions of the plurality of active regions.

12. The semiconductor structure as claimed in claim 1, wherein the detection element is disposed between two adjacent active regions of the plurality of active regions.

13. The semiconductor structure as claimed in claim 1, wherein the word line further comprises:
a first dielectric layer disposed on the substrate;
a first conductive layer disposed on the first dielectric layer;
a second conductive layer disposed on the first conductive layer; and
a second dielectric layer disposed on the second conductive layer,
wherein the opening exposes the second dielectric layer.

14. The semiconductor structure as claimed in claim 13, wherein the word line further comprises:
a first liner disposed between the first dielectric layer and the first conductive layer; and
a second liner disposed between the first conductive layer and the second conductive layer, wherein the first liner and the second liner surround the first conductive layer.

15. The semiconductor structure as claimed in claim 1, further comprising:
a mask structure disposed between the word line and the bit line conductive layer, wherein the opening penetrates the mask structure.

16. A method of forming a semiconductor structure, comprising:
providing a substrate;
forming an isolation region comprising a detection element in the substrate, wherein the isolation region defines a plurality of active regions;
forming a word line in the substrate and in the plurality of active regions;
forming a bit line conductive layer on the word line; and
forming an opening in the bit line conductive layer, such that the opening penetrates the bit line conductive layer and exposes the word line and the plurality of active regions, so that the opening is in contact with the detection element.

17. The method as claimed in claim 16, further comprising:
performing a cleaning process to remove the detection element through the opening.

18. The method as claimed in claim 17, wherein the formation of the word line in the substrate further comprises:
forming a trench in the substrate;
forming a first dielectric layer in the trench;
forming a first conductive layer on the first dielectric layer;
forming a second conductive layer on the first conductive layer; and
forming a second dielectric layer on the second conductive layer,
wherein the opening exposes the second dielectric layer.

19. The method as claimed in claim 18, wherein the formation of the word line in the substrate further comprises:
forming a first liner between the first dielectric layer and the first conductive layer; and
forming a second liner between the first conductive layer and the second conductive layer, wherein the first liner and the second liner surround the first conductive layer.

20. The method as claimed in claim 19, wherein the cleaning process is performed to remove the first liner and the first conductive layer of the word line through the opening.
